(19) United States
(12) Patent Application Publication
(10) Pub. No.: US 2013/0045607 A1
(43) Pub. Date: Feb. 21, 2013

(54) PATTERN GENERATING APPARATUS, PATTERN GENERATING PROGRAM, AND METHOD FOR FABRICATING SEMICONDUCTOR DEVICE

(71) Applicants: Ai INOUE, Kanagawa (JP); Takashi Nakazawa, Kanagawa (JP); Takashi Obara, Kanagawa (JP); Kazuyuki Masukawa, Kanagawa (JP); Takaki Hashimoto, Kanagawa (JP)

(72) Inventors: Ai INOUE, Kanagawa (JP); Takashi Nakazawa, Kanagawa (JP); Takashi Obara, Kanagawa (JP); Kazuyuki Masukawa, Kanagawa (JP); Takaki Hashimoto, Kanagawa (JP)

(21) Appl. No.: 13/422,677

(22) Filed: Mar. 16, 2012

(30) Foreign Application Priority Data
Aug. 17, 2011 (JP) 2011-178473

(51) Int. Cl. H01L 21/32; G06F 17/50; G03B 27/72

(52) U.S. Cl. 438/761; 355/35; 716/52; 257/E21.258

(57) ABSTRACT

According to one embodiment, a pattern generating apparatus includes a light intensity calculating part that calculates light intensity at a pattern to be formed based on exposure and light intensity at the periphery of the pattern, a light intensity evaluating part that evaluates the light intensities at the pattern and the periphery of the pattern, and a data output part that outputs correction data for the pattern based on the results of the evaluation by the light intensity part.

### CROSS-REFERENCE TO RELATED APPLICATIONS

This application is based upon and claims the benefit of priority from Japanese Patent Application No. 2011-178473, filed on Aug. 17, 2011; the entire contents of which are incorporated herein by reference.

### FIELD

Embodiments described herein relate generally to pattern generating apparatuses, pattern generating programs, and methods for fabricating a semiconductor device.

### BACKGROUND

With the further miniaturization of semiconductor devices in recent years, resist patterns used in lithography process have also been made finer, for example, line widths have been made smaller to the order of tens of nanometers.

Since resist patterns have been made finer to the order of tens of nanometers and since resist films have been made thinner, resist patterns have sometimes collapsed, and parting defects have sometimes resulted.

### BRIEF DESCRIPTION OF THE DRAWINGS

FIG. 1A is a schematic block diagram of a pattern generating apparatus according to a first embodiment and peripheral devices for the same; FIG. 1B is a schematic cross-sectional view of an exposure apparatus for which the pattern generating apparatus of FIG. 1A is used; FIGS. 1C and 1D are a cross-sectional view of a semiconductor device showing a method for fabricating the semiconductor device by using the pattern generating apparatus of FIG. 1A;

FIG. 2 is a block diagram of hardware of a pattern generating apparatus according to a second embodiment;

FIG. 3A is a plan view of one example of an optical image to be judged at a pattern generating apparatus according to a third embodiment; FIG. 3B is a graph showing one example of a method of calculating a judgment index to pillar collapse based on an image intensity distribution in the optical image of FIG. 3A;

FIG. 4A is a cross-sectional view of one example of a mask pattern according to a fourth embodiment; FIG. 4B is a graph showing a method of calculating a judgment index to pillar collapse based on an image intensity distribution produced with the mask pattern of FIG. 4A; FIG. 4C is a cross-sectional view of one example of a resist pattern corresponding to the image intensity distribution in FIG. 4B;

FIG. 5A is a cross-sectional view of one example of a mask pattern according to a fifth embodiment; FIG. 5B is a graph showing one example of a method of calculating a judgment index to pillar collapse based on an image intensity distribution produced with the mask pattern of FIG. 5A; FIG. 5C is a cross-sectional view of one example of a resist pattern corresponding to the image intensity distribution in FIG. 5B;

FIG. 6 is a graph showing the relationship between light intensity volume ratios and collapse limit sizes based on a comparison between the case of having used the mask pattern of FIG. 4A and the case of having used the mask pattern of FIG. 5A;

FIG. 7 is a flowchart of a method for generating a pattern according to a sixth embodiment;

FIG. 8 is a chart showing the conformity region of the depth of focus, exposure latitude, and a judgment index to pillar collapse for each set of conditions;

FIG. 9A is a cross-sectional view of one example of a mask pattern according to a seventh embodiment; FIG. 9B is a graph showing one example of a method of calculating a judgment index to pillar collapse based on an image intensity distribution produced with the mask pattern of FIG. 9A;

FIG. 10A is a cross-sectional view of one example of a mask pattern according to an eighth embodiment; FIG. 10B is a graph showing one example of a method of calculating a judgment index to pillar collapse based on an image intensity distribution produced with the mask pattern of FIG. 10A;

FIG. 11A is a cross-sectional view of one example of a mask pattern according to a ninth embodiment; FIG. 11B is a graph showing one example of a method of calculating a judgment index to parting defects based on an image intensity distribution produced with the mask pattern of FIG. 11A; FIG. 11C is a cross-sectional view of one example of a resist pattern corresponding to the image intensity distribution in FIG. 11B;

FIG. 12A is a cross-sectional view of one example of a mask pattern according to a tenth embodiment; FIG. 12B is a graph showing one example of a method of calculating a judgment index to parting defects based on an image intensity distribution produced with the mask pattern of FIG. 12A; FIG. 12C is a cross-sectional view of one example of a resist pattern corresponding to the image intensity distribution in FIG. 12B;

FIG. 13 is a graph showing the relationship between light intensity volume ratios and unopened hole defectives based on a comparison between the case of having used the mask pattern of FIG. 11A and the case of having used the mask pattern of FIG. 12A;

FIG. 14 is a chart showing the conformity region of the depth of focus, exposure latitude, and a judgment index to parting defects for each set of conditions;

FIG. 15A is a plan view of exemplary mask patterns according to an eleventh embodiment; FIG. 15B is a plan view of exemplary mask patterns according to a twelfth embodiment; FIG. 15C is a plan view of exemplary mask patterns according to a thirteenth embodiment; FIG. 15D is a plan view of exemplary mask patterns according to a fourteenth embodiment;

FIG. 16 is a graph showing the relationship between light intensity volume ratios and collapse limit sizes based on a comparison between the case of having used the mask patterns of FIG. 15A and the case of having used the mask patterns of FIG. 15B;

FIG. 17A is a plan view of one example of an optical image to be judged at a pattern generating apparatus according to a fifteenth embodiment; FIG. 17B is an illustration showing one example of a method of calculating a judgment index to pillar collapse based on an image intensity distribution in the optical image in FIG. 17A; FIG. 17C is a plan view of another example of the optical image to be judged at the pattern generating apparatus according to the fifteenth embodiment; FIG. 17D is an illustration showing one example of a method of calculating a judgment index to pillar collapse based on an image intensity distribution in the optical image in FIG. 17C; FIG. 17E is a graph showing a comparison between total latent image intensity at the foot of a pillar pattern of FIG. 17B and total latent image intensity at the foot of a pillar pattern of FIG. 17D;

FIGS. 18A and 18B are illustrations showing the occurrence and the nonoccurrence of pillar collapse at the time when having changed a focus and the amount of exposure in a wafer surface;

FIG. 19A is a cross-sectional view of one example of a resist film structure according to a sixteenth embodiment; FIG. 19B is a cross-sectional view of another example of the resist film structure according to the sixteenth embodiment; and

FIG. 20 is a graph showing the relationship between light intensity volume ratios and collapse limit sizes based on a comparison between the case of having used the resist film structure of FIG. 19A and the case of having used the resist film structure of FIG. 19B.

### DETAILED DESCRIPTION

Pattern generating apparatuses according to the present embodiments are each provided with a light intensity calculating part, a light intensity evaluating part, and a data output part. The light intensity calculating part calculates light intensity at a pattern to be formed based on exposure and light intensity at the periphery of the pattern. The light intensity evaluating part evaluates the light intensity at the pattern and the light intensity at the periphery of the pattern. The data output part outputs correction data for the pattern based on the results of the evaluations by the light intensity evaluating part.

The pattern generating apparatuses and the methods for fabricating a semiconductor device according to the present embodiments will be described below with reference to the accompanying drawings. Note that the present invention is not limited to the following embodiments.

### First Embodiment

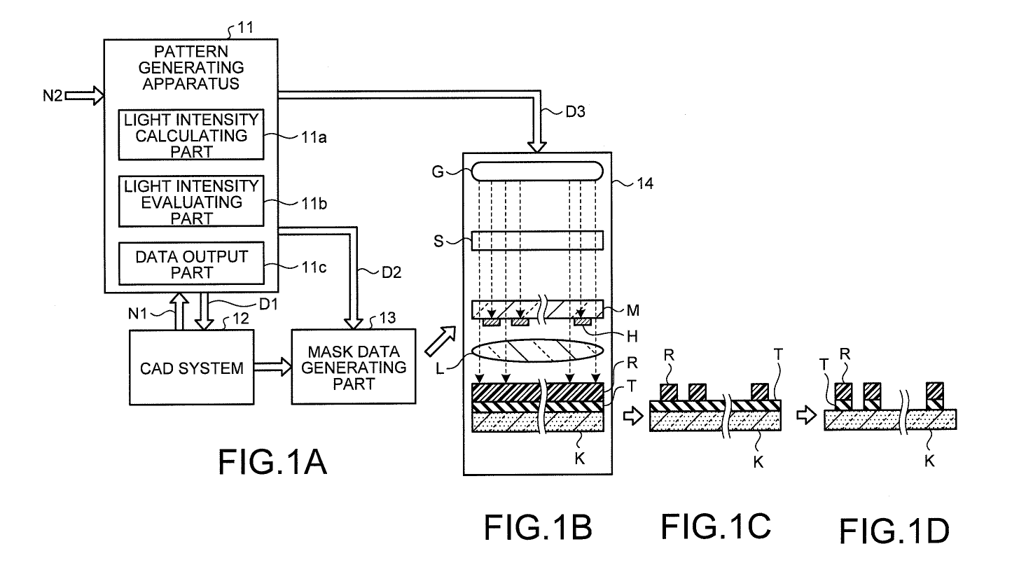

FIG. 1A is a schematic block diagram of a pattern generating apparatus according to a first embodiment and peripheral devices for the pattern generating apparatus. FIG. 1B is a schematic cross-sectional view of an exposure apparatus for which the pattern generating apparatus of FIG. 1A is used. FIGS. 1C and 1D are a cross-sectional view of a semiconductor device showing a method for fabricating the semiconductor device by using the pattern generating apparatus of FIG. 1A.

As shown in FIG. 1A, the pattern generating apparatus 11 is provided with a light intensity calculating part 11a, a light intensity evaluating part 11b, and a data output part 11c. As the peripheral devices for the pattern generating apparatus 11, a CAD system 12 and a mask data generating part 13 are provided. And further, as shown in FIG. 1B, the exposure apparatus 14 is provided with a light source G, a stop S, a photo mask M, and a lens L.

The light intensity calculating part 11a can calculate light intensity at a pattern to be formed based on exposure and light intensity at the periphery of the pattern. Incidentally, the light intensities can be calculated by a lithography simulation. The light intensity evaluating part 11b can evaluate the light intensity at the pattern and the light intensity at the periphery of the pattern calculated by the light intensity calculating part 11a. The data output part 11c can output correction data for the pattern to be formed based on the exposure based on the results of the evaluations by the light intensity evaluating part 11b.

As an evaluation index for evaluating the light intensity at the pattern to be formed based on the exposure and the light intensity at the periphery of the pattern, it is possible to use the volume ratio between the light intensity at the pattern and the light intensity at the periphery of the pattern, the ratio between the maximum value and the minimum value of the light intensities at the pattern and the periphery of the pattern, or light intensity at the cross-section foot of the periphery of the pattern.

As the correction data for the pattern to be formed based on the exposure, it is possible to cite correction data D1 for layout design data N1 corresponding to the pattern, correction data D2 for a mask pattern corresponding to the pattern, or correction data D3 for exposure conditions to be met for the formation of the pattern.

Semiconductor integrated circuit layout design data N1 is generated at the CAD system 12 and then sent to the pattern generating apparatus 11. And further, to the pattern generating apparatus 11 is performed an input about the exposure conditions N2 met for the formation of the pattern based on the exposure.

The light intensity calculating part 11a calculates light intensity at the pattern to be formed based on exposure and light intensity at the periphery of the pattern, following which the results of the calculations are communicated to the light intensity evaluating part 11b. Thereafter, the light intensity evaluating part 11b determines whether an evaluation index to the light intensities at the pattern and the periphery of the pattern corresponds with a predetermined value. Then the data output part 11c generates correction data D1, D2, and D3 such that the evaluation index to the light intensities at the pattern and the periphery of the pattern corresponds with the predetermined value, after which the correction data D1, D2, and D3 are respectively sent to the CAD system 12, the mask data generating part 13, and the exposure apparatus 14.

After the CAD system 12 has received the correction data D1 from the pattern generating apparatus 11, the layout design data N1 is corrected based on the correction data D1, and then sent to the mask data generating part 13.

Then the mask data generating part 13 generates mask data corresponding to a layout pattern designated in the form of the layout design data N1. Thereafter, a mask pattern specified in the form of the mask data generated at the mask data generating part 13 is formed on the photo mask M by using a light shielding film H.

In the case where correction data D2 has been sent from the pattern generating apparatus 11, the mask data is corrected based on the correction data D2. Incidentally, as a method for correcting the mask data, an assist pattern having a size not larger than the value of a resolution limit at the time of the exposure can be added to the layout pattern designated in the form of the layout design data N1. And further, the assist pattern can be formed such that the light intensity volume ratio at the pattern to be transferred to a resist film R and the periphery of the pattern are lowered. Or alternatively, the assist pattern may be formed such that the ratio between the maximum value and the minimum value of the light intensities at the pattern to be transferred to the resist film R and the periphery of the pattern is lowered or such that light intensity at the cross-section foot of the periphery of the pattern to be transferred to the resist film R is lowered.

On a semiconductor substrate K, an underlying layer T is formed. To the underlying layer T, the resist film R is applied. Incidentally, the underlying layer T may be an insulator film such as a silicon oxide film or a silicon nitride film, a semiconductor film such as an amorphous silicon film or a polycrystalline silicon film, or a metal film such as an Al film or a Cu film.

Then, as shown in FIG. 1B, the light source G radiates exposure light such as ultraviolet light, and the exposure light is narrowed by the stop S and sent to the resist film R via the photo mask M and the lens L, whereby the resist film R is exposed.

In the case where correction data D3 has been sent from the pattern generating apparatus 11, the exposure conditions are modified based on the correction data D3. Incidentally, as examples of the exposure conditions, it is possible to cite a lighting form, the NA (Numerical Apertures) of the optical lighting system, an irradiation wavelength, a resist material, polarization, focus, aberration and the amount of exposure (exposure intensity and exposure time).

After the exposure of the resist film R, as shown in FIG. 1C, the resist film R is developed to transfer the mask pattern of the photo mask M to the resist film R.

Then, as shown in FIG. 1D, the underlying layer T is processed using the mask pattern-transferred resist film R as a mask to transfer the mask pattern of the photo mask M to the underlying layer T. Incidentally, as the processing of the underlying layer T, etching processing may be performed, or ion implantation may be performed.

In this embodiment, by generating correction data D1 to D3 based on light intensity at a resist pattern to be formed on the resist film R and light intensity at the periphery of the pattern, the contrast between the light intensity at the resist pattern and the light intensity at the periphery of the pattern can be lowered or heightened. Because of this, the use of a positive resist pattern allows light intensity at the periphery of the resist pattern to be lessened, and allows tailing of the resist pattern to be produced easily, and the collapse of the resist pattern can, therefore, be reduced. On the other hand, with a negative resist pattern, by heightening the contrast between light intensity at the resist pattern and light intensity at the periphery of the pattern, the number of parting defects of the resist pattern can be reduced. And further, only light intensity at a resist pattern or only light intensity at the periphery of a resist pattern can also be evaluated.

### Second Embodiment

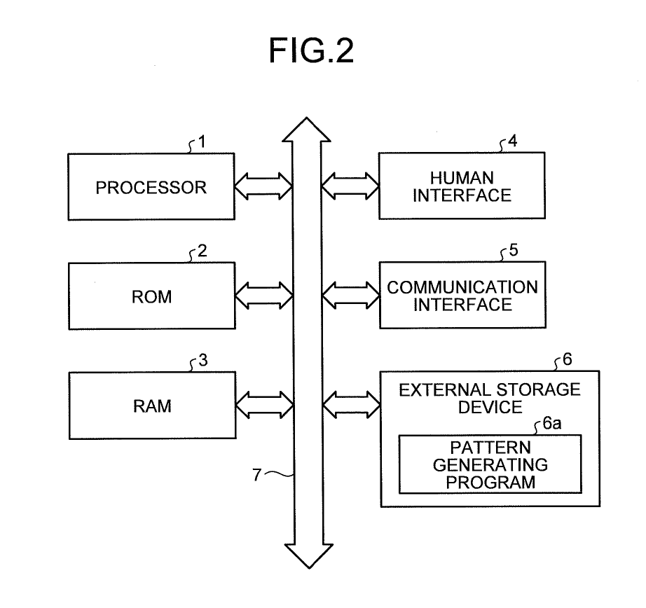

FIG. 2 is a block diagram of hardware of a pattern generating apparatus according to a second embodiment.

As shown in FIG. 2, the pattern generating apparatus 11 can be provided with a processor 1 including a CPU and so on, ROM 2 that stores fixed data, RAM 3 that provides the processor 1 with a work area and so on, a human interface 4 that makes persons and computer touch each other, a communication interface 5 that provides means for communicating with the outside, and an external storage device 6 that stores programs for operating the processor 1 and various pieces of data. The processor 1, the ROM 2, the RAM 3, the human interface 4, the communication interface 5, and the external storage device 6 are coupled to one another via a bus 7.

As the external storage device 6, it is possible to use a magnetic disk such as a hard disk, an optical disk such as a DVD, or a portable semiconductor storage device such as a USB memory or a memory card, for example. As the human interface 4, a keyboard, a mouse, or touch panel, for example, can be used as an input interface, and a display or a printer, for example, can be used as an output interface. As the communication interface 5, a LAN card, a modem, or a router for connection with the Internet and a LAN can be used, for example.

In the external storage device 6 is installed a pattern generating program 6a for the output of correction data for a pattern based on light intensity at the pattern to be formed based on exposure and light intensity at the periphery of the pattern.

When the pattern generating program 6a has been executed by the processor 1, correction data D1 to D3 are generated based on light intensity at a pattern to be formed based on exposure and light intensity at the periphery of the pattern, following which the correction data D1, D2, and D3 are respectively sent to the CAD system 12, the mask data generating part 13, and the exposure apparatus 14.

The pattern generating program 6a that is executed by the processor 1 may be stored in the external storage device 6 to load the program 6a into the RAM 3 at the time of the execution of the program 6a, may be stored in the ROM 2 in advance, or may be installed via the communication interface 5. And further, the pattern generating program 6a may be executed by a stand-alone computer or may be executed by a cloud computer.

### Third Embodiment

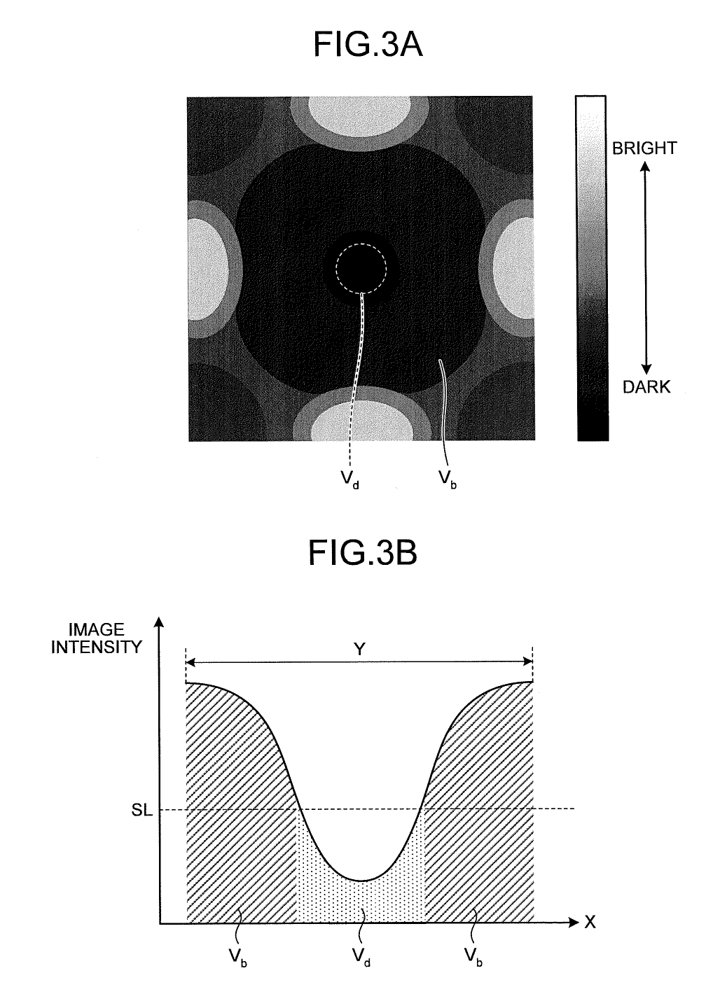

FIG. 3A is a plan view of one example of an optical image to be judged at a pattern generating apparatus according to a third embodiment, and FIG. 3B is a graph showing one example of a method of calculating a judgment index to pillar collapse based on an image intensity distribution in the optical image in FIG. 3A.

With the optical image at the time when pillar patterns have been formed as a resist pattern, as shown in FIGS. 3A and 3B, portions representing the pillar patterns are dark, and the peripheries of the portions are bright. That is, with positive-acting resists, portions represented as dark portions in optical images of the resists are left, but portions represented as bright portions in the optical images are removed.

As can be seen from FIGS. 3A and 3B, the light intensity volume ratio between the pillar pattern and the periphery of the pillar pattern can be expressed by the expression V_{b}/(V_{b}+V_{d}) where V_{d} is the dark portion volume of the dark portion representing the formation of the pillar pattern, and V_{b} is the bright portion volume of the bright portion representing the periphery of the pillar pattern. Likewise, with hole patterns, the light intensity volume ratio between the hole pattern and the periphery of the hole pattern can be expressed by the expression V_{b}/(V_{b}+V_{d}) where V_{b} is the bright portion volume of a bright portion representing the formation of the hole pattern, and V_{d} is the dark portion volume of a dark portion representing the periphery of the hole pattern. Therefore layout design data, mask data, or exposure conditions can be set such that the above light intensity volume ratios correspond with predetermined values.

In the case where the pillar patterns are formed at regular intervals, from the viewpoint of judgment index calculation accuracy and so on, it is preferable that the spacing between the opposite sides of the boundary of the periphery of the pillar patterns be set at Y when assuming that the spacing between the centers of the pillar patterns is Y. And further, as for an isolated pattern, it is preferable that the boundary of its periphery be set at the middle of the isolated pattern and adjacent patterns.

### Fourth Embodiment

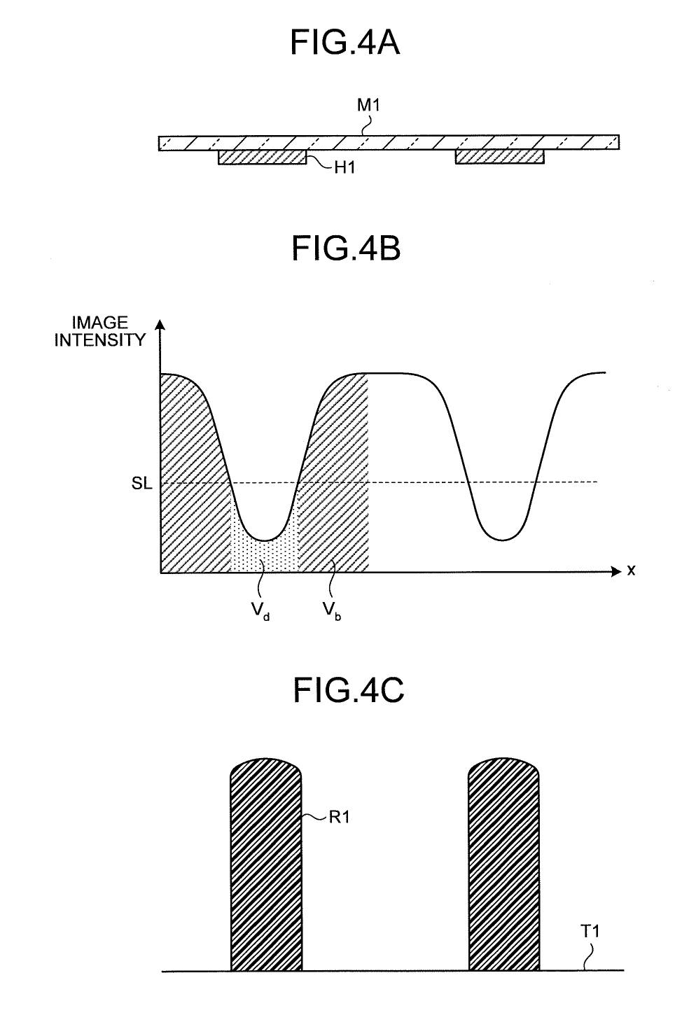

FIG. 4A is a cross-sectional view of one example of a mask pattern according to a fourth embodiment. FIG. 4B is a graph showing a method of calculating a judgment index to pillar collapse based on an image intensity distribution produced with the mask pattern of FIG. 4A. FIG. 4C is a cross-sectional view of one example of a resist pattern corresponding to the image intensity distribution in FIG. 4B.

Referring to FIG. 4A, on a photo mask M1, a light shielding film H1 is formed as the mask pattern. In the case where the exposure of an underlying layer T1 has been performed using the photo mask M1, an image intensity distribution at the underlying layer T1 is as shown in FIG. 4B, i.e., portions under the light shielding film H1 are dark, but the peripheries of the above portions are bright. Therefore, as shown in FIG. 4C, a resist film R1 is patterned in correspondence to the image intensity distribution in FIG. 4B, i.e., pillar patterns are formed at the resist film R1.

At the time of a judgment of the collapsibility of the pillar patterns formed at the resist film R1, light intensities at the pillar patterns formed at the resist film R1 and light intensities at the peripheries of the pillar patterns can be evaluated. As an evaluation index used at the time of the above evaluation, the foregoing light intensity volume ratio V_{b}/(V_{b}+V_{d}) can be used. In the case where the light intensities at the peripheries of the pillar patterns are higher, a latent image intensity distribution is produced clearly at the portions left as the pillar patterns of the resist film R1 too, and thus the fusibility of the resist film R1 left as the pillar pattern portions increases, whereby the pillar patterns tend to collapse. Therefore, by reducing the light intensities at the peripheries of the pillar patterns such that the light intensity volume ratio V_{b}/(V_{b}+V_{d}) corresponds to the predetermined value, the pillar patterns can be made to collapse less easily.

### Fifth Embodiment

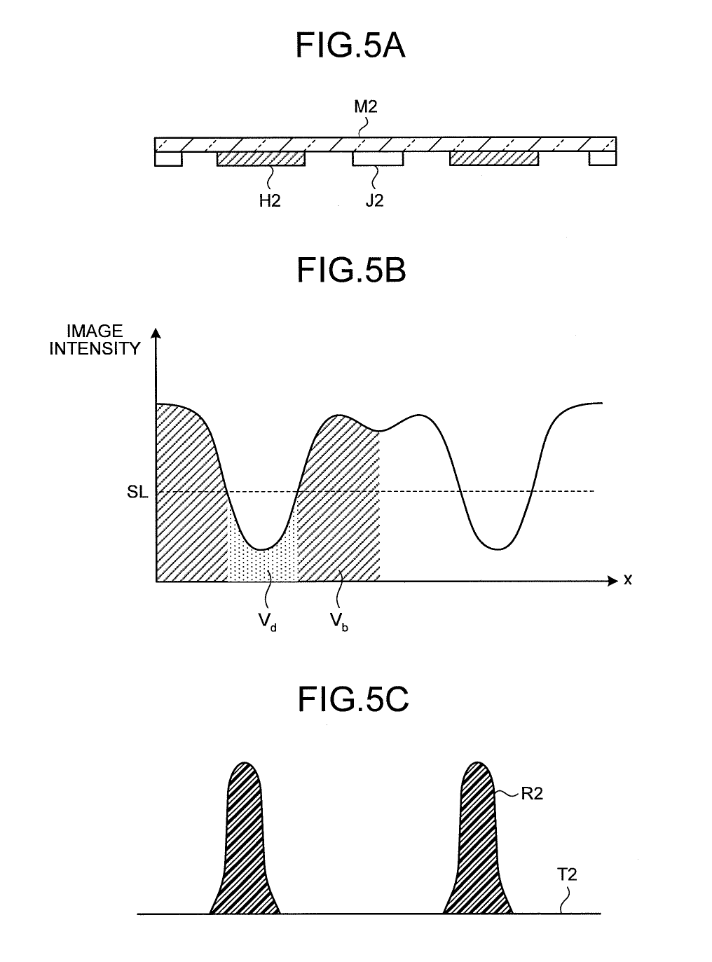

FIG. 5A is a cross-sectional view of one example of a mask pattern according to a fifth embodiment. FIG. 5B is a graph showing one example of a method of calculating a judgment index to pillar collapse based on an image intensity distribution produced with the mask pattern of FIG. 5A. FIG. 5C is a cross-sectional view of one example of a resist pattern corresponding to the image intensity distribution in FIG. 5B.

Referring to FIG. 5, on a photo mask M2, a light shielding film H2 is formed as the mask pattern, and a light shielding film J2 is formed as an assist pattern. Note that there is a need to set the size of the assist pattern at a value not larger than the value of a resolution limit at the time of the exposure of a resist film R2. And further, the assist pattern can be formed such that the intensity of exposure light at the periphery of the mask pattern is lessened. In the case where the exposure of an underlying layer T2 has been performed using the photo mask M2, an image intensity distribution at the underlying layer T2 is as shown in FIG. 5B, i.e., portions under the light shielding film H2 are dark, but the peripheries of the above portions are bright. Likewise, the portions under the light shielding film J2 of the underlying layer T2 are low in brightness. Therefore, as shown in FIG. 5C, when the resist film R2 has been patterned in correspondence to the image intensity distribution in FIG. 5B, pillar patterns are formed at the resist film R2 such that the pillar patterns tail slightly on the underlying layer T2, and the pillar patterns can, therefore, be made to collapse less easily.

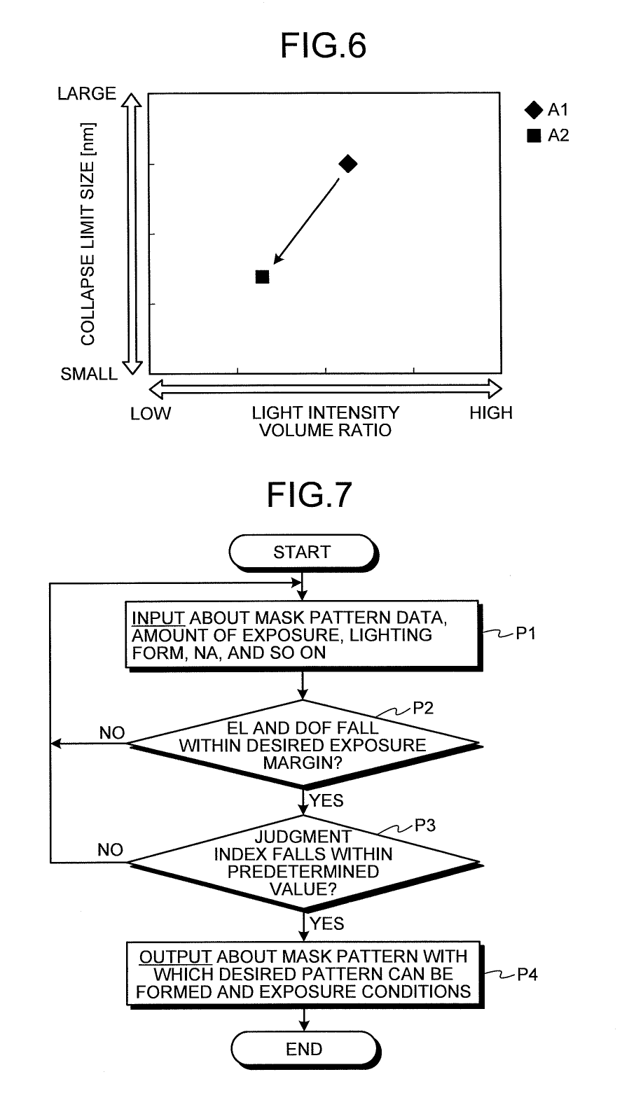

FIG. 6 is a graph showing the relationship between the light intensity volume ratios and collapse limit sizes based on a comparison between the case of having used the mask pattern of FIG. 4A (case A1) and the case of having used the mask pattern of FIG. 5A (case A2).

Referring to FIG. 6, in the case where the pillar patterns of FIG. 5C are formed at the resist film R2, the light intensity volume ratio is low compared with the case where the pillar patterns of FIG. 4 are formed at the resist film R1, and thus the collapse limit size of the pillar patterns is small. Therefore the collapse of the pillar patterns decreases, and hence the finer pillar patterns can be implemented.

### Sixth Embodiment

FIG. 7 is a flowchart of a method for generating a pattern according to a sixth embodiment.

As shown in FIG. 7, a lithography simulation is performed using input about mask pattern data generated based on layout design data, the amount of exposure, the lighting form, Numerical Apertures, and so on (Step P1).

Then, whether the depth of focus (DOE) and exposure latitude (EL) fall within a desired exposure margin is determined (Step P2). When the depth of focus DOF and the exposure latitude EL fall within the desired exposure margin, whether the judgment index falls within the predetermined value is determined (Step P3). When the judgment index falls within the predetermined value, output about a mask pattern with which a desired pattern can be formed and exposure conditions is performed (Step P4).

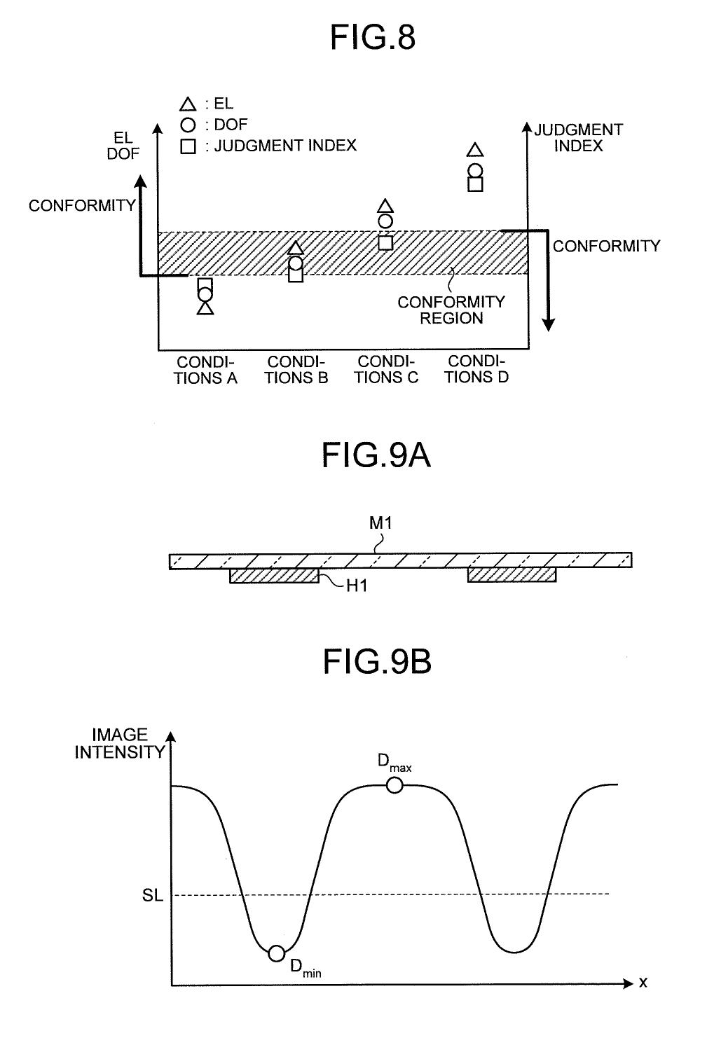

FIG. 8 is a chart showing the conformity region of the depth of focus, the exposure latitude, and the judgment index to the pillar collapse for each set of conditions.

In FIG. 8, conditions A to D, for example, are shown. With the conditions A, it is assumed that the judgment index falls within the predetermined value, but the depth of focus and the exposure latitude do not fall within the desired exposure margin. With the conditions B and C, it is assumed that the judgment index falls within the predetermined value, and the depth of focus and the exposure latitude fall within the desired exposure margin. With the conditions D, it is assumed that the depth of focus and the exposure latitude fall within the desired exposure margin, but the judgment index does not fall within the predetermined value. Therefore, in order to decrease the pillar collapse, the conditions B or C can be selected. Incidentally, the conditions A to D each include the shape of the mask pattern, the amount of exposure, the lighting form, Numerical Apertures that are changed as appropriate.

### Seventh Embodiment

FIG. 9A is a cross-sectional view of one example of a mask pattern according to a seventh embodiment, and FIG. 9B is a graph showing one example of a method of calculating a judgment index to pillar collapse based on an image intensity distribution produced with the mask pattern of FIG. 9A.

The mask pattern and the image intensity distribution shown in FIGS. 9A and 9B are the same as the mask pattern and the image intensity distribution shown in FIGS. 4A and 4B; whereas FIG. 4B shows the method of using the light intensity volume ratio V_{b}/(V_{b}+V_{d}) as the judgment index, FIG. 9B shows the method in which the ratio between the maximum value Dₘₐₓ and the minimum value Dₘᵢₙ of the light intensity of exposure light can be used.

### Eighth Embodiment

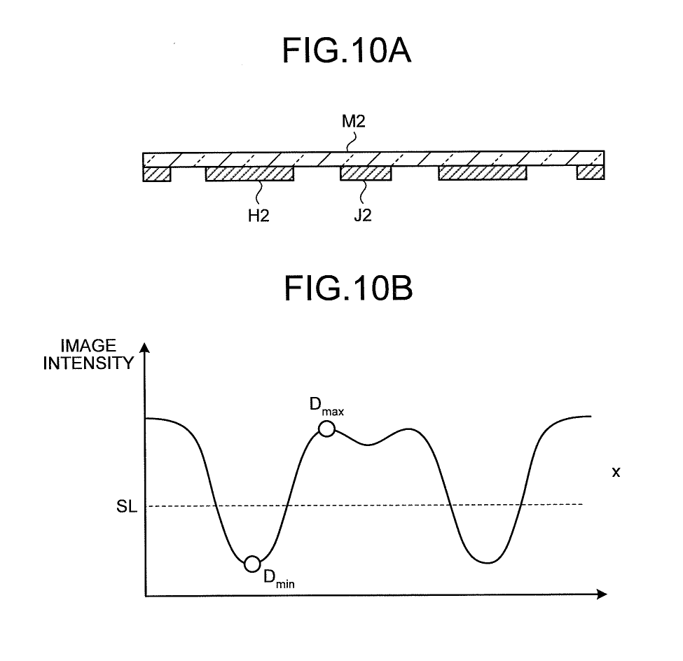

FIG. 10A is a cross-sectional view of one example of a mask pattern according to an eighth embodiment, and FIG. 10B is a graph showing one example of a method of calculating a judgment index to pillar collapse based on an image intensity distribution produced with the mask pattern of FIG. 10A.

The mask pattern and the image intensity distribution shown in FIGS. 10A and 10B are the same as the mask pattern and the image intensity distribution shown in FIGS. 5A and 5B; whereas FIG. 5B shows the method of using the light intensity volume ratio V_{b}/(V_{b}+V_{d}) as the judgment index, FIG. 10B shows the method in which the ratio between the maximum value Dₘₐₓ and the minimum value Dₘᵢₙ of the light intensity of exposure light can be used.

### Ninth Embodiment

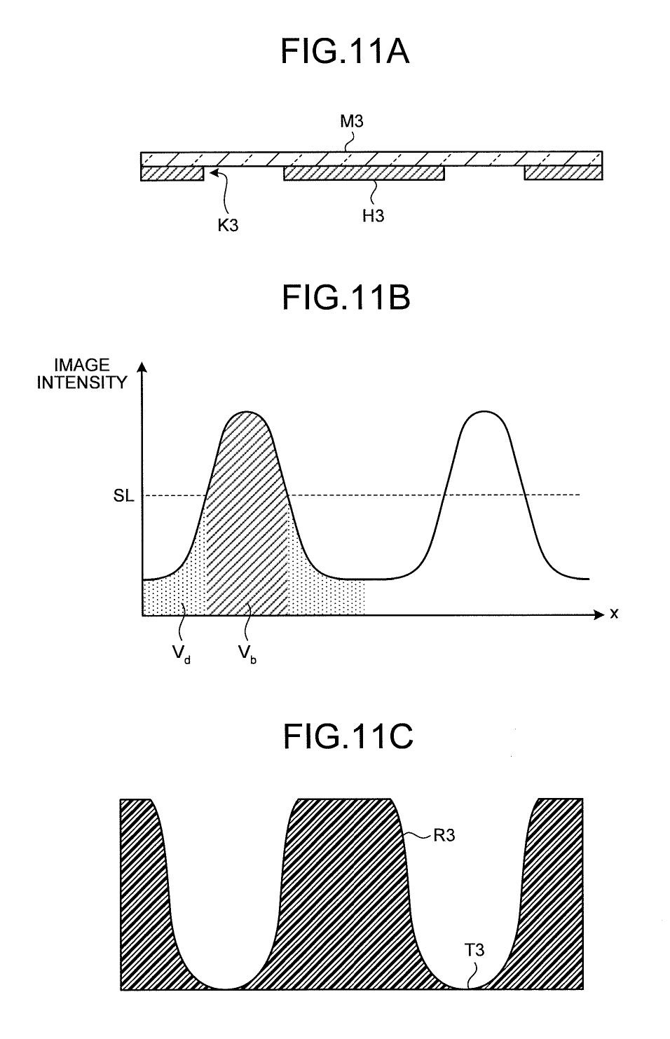

FIG. 11A is a cross-sectional view of one example of a mask pattern according to a ninth embodiment. FIG. 11B is a graph showing one example of a method of calculating a judgment index to parting defects based on an image intensity distribution produced with the mask pattern of FIG. 11A. FIG. 11C is a cross-sectional view of one example of a resist pattern corresponding to the image intensity distribution in FIG. 11B.

Referring to FIG. 11, on a photo mask M3, a light shielding film H3 is formed; at the light shielding film H3, opening patterns K3 are formed as a mask pattern. In the case where the exposure of an underlying layer T3 is performed using the photomask M3, the image intensity distribution at the underlying layer T3 is as shown in FIG. 11B, i.e., portions under the opening patterns K3 are bright, but the peripheries of the above portions are dark. Therefore, as shown in FIG. 11C, a resist film R3 is patterned in correspondence to the image intensity distribution in FIG. 11B, and thus open-hole patterns are formed at the resist film R3.

When judging the partibility of the processed pattern formed at the resist film R3, light intensities at the open-hole pattern portions formed at the resist film R3 and light intensities at the peripheries of the open-hole pattern portions can be used. As an evaluation index to the partibility, the light intensity volume ratio V_{b}/(V_{b}+V_{d}) can be used. When light intensities at the open-hole pattern portions are low compared with light intensities at the peripheries of the open-hole pattern portions, the fusibility of the opening pattern portions at the resist film R3 decreases, and thus the open-hole patterns tend to part from the resist film R3 less easily. Because of this, it is necessary that the light intensity volume ratio V_{b}/(V_{b}+V_{d}) correspond to the predetermined value.

### Tenth Embodiment

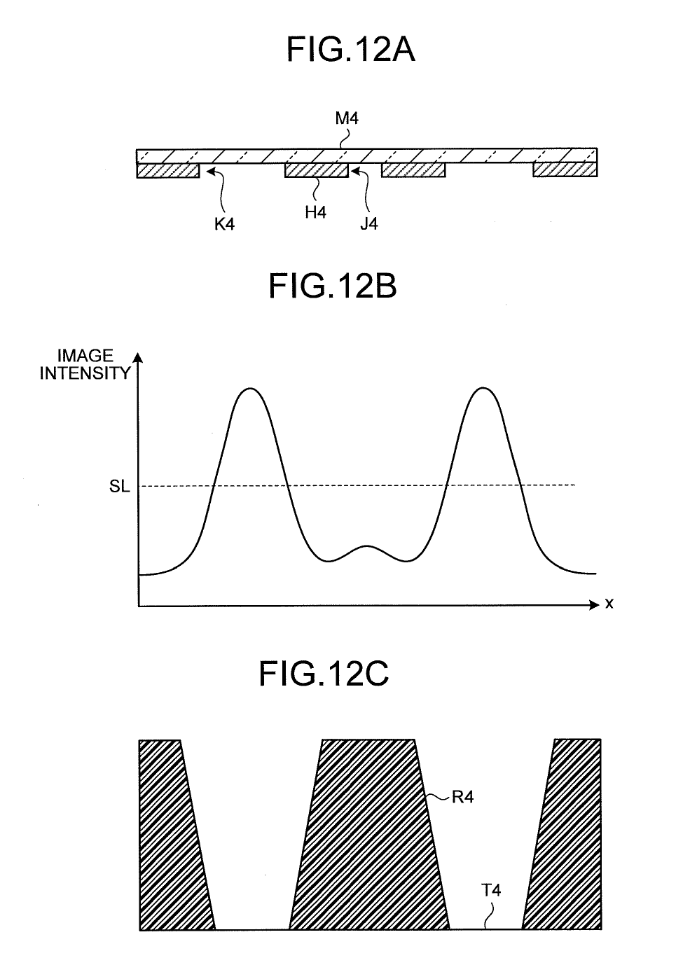

FIG. 12A is a cross-sectional view of one example of a mask pattern according to a tenth embodiment. FIG. 12B is a graph showing a method of calculating a judgment index to parting defects based on an image intensity distribution produced with the mask pattern of FIG. 12A. FIG. 12C is a cross-sectional view of one example of a resist pattern corresponding to the image intensity distribution in FIG. 12B.

Referring to FIG. 12, on a photo mask M4, a light shielding film H4 is formed: at the light shielding film H4, opening patterns K4 are formed as a mask pattern, and opening patterns J4 are formed as an assist pattern. Note that there is a need to set the size of the assist pattern at a value not larger than the value of a resolution limit at the time of the exposure of the resist film R4. And further, the assist pattern can be formed such that the volume ratio between exposure light intensity at the mask pattern and exposure light intensity at the periphery of the mask pattern heightens. In the case where the exposure of an underlying layer T4 is performed using the photo mask M4, the image intensity distribution on the underlying layer T4 is as shown in FIG. 12B, i.e., portions under the opening patterns K4 are bright; and besides, at the portions under the peripheries of the opening patterns K4 of the underlying layer T4, brightness at portions under the opening pattern J4 increases. Therefore, as shown in FIG. 12C, when the resist film R4 has been patterned in correspondence to the image intensity distribution in FIG. 12B, open-hole patterns are formed steeply at the resist film R4, that is, it is possible to easily part open-hole patterns.

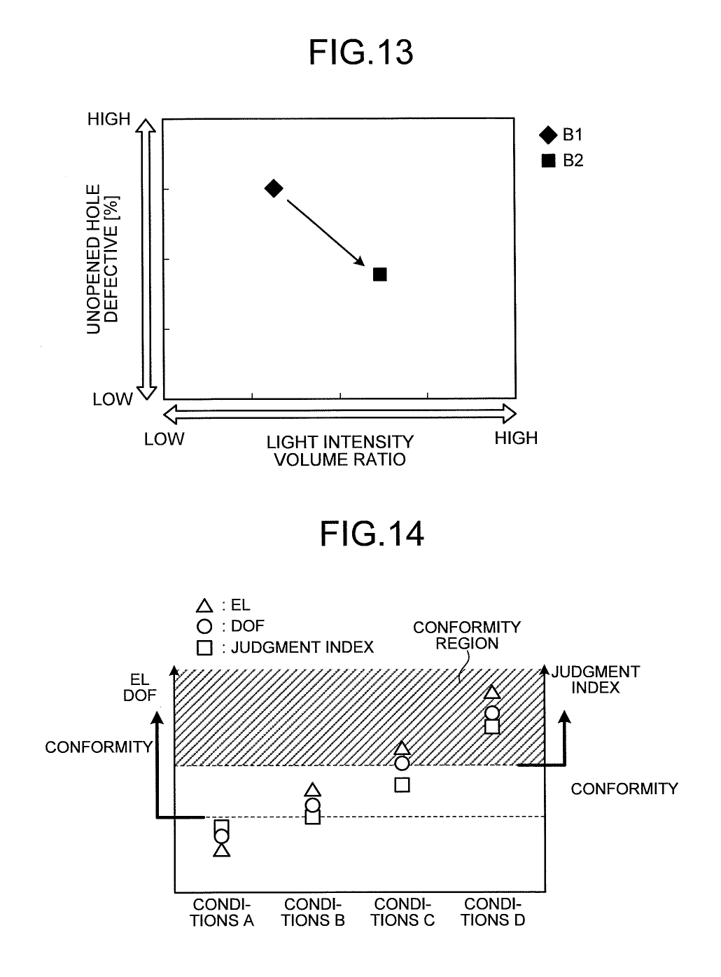

FIG. 13 is a graph showing the relationship between the light intensity volume ratios and unopened hole defectives based on a comparison between the case of having used the mask pattern of FIG. 11A (case B1) and the case of having used the mask pattern of FIG. 12A (case B2).

FIG. 13 shows that in the case of having formed such open-hole patterns at the resist film R4, the light intensity volume ratio is high compared with the formation of the open-hole patterns at the resist film R3, and thus the number of unopened hole defects decreases. Because of this, the finer open-hole patterns can be implemented.

FIG. 14 is a chart showing the conformity region of the depth of focus, exposure latitude, and a judgment index to parting defects for each set of conditions.

In FIG. 14, conditions A to D, for example, are shown. With the conditions A, it is assumed that the judgment index does not fall within a predetermined value, and the depth of focus and the exposure latitude do not fall within a desired exposure margin. With the conditions B and C, it is assumed that the depth of focus and the exposure latitude fall within the desired exposure margin, but the judgment index does not fall within the predetermined value. With the conditions D, it is assumed that the judgment index falls within the predetermined value, and the depth of focus and the exposure latitude fall within the desired exposure margin. In this embodiment, to easily part the open-hole patterns, the conditions D can be selected.

### Eleventh to Fourteenth Embodiments

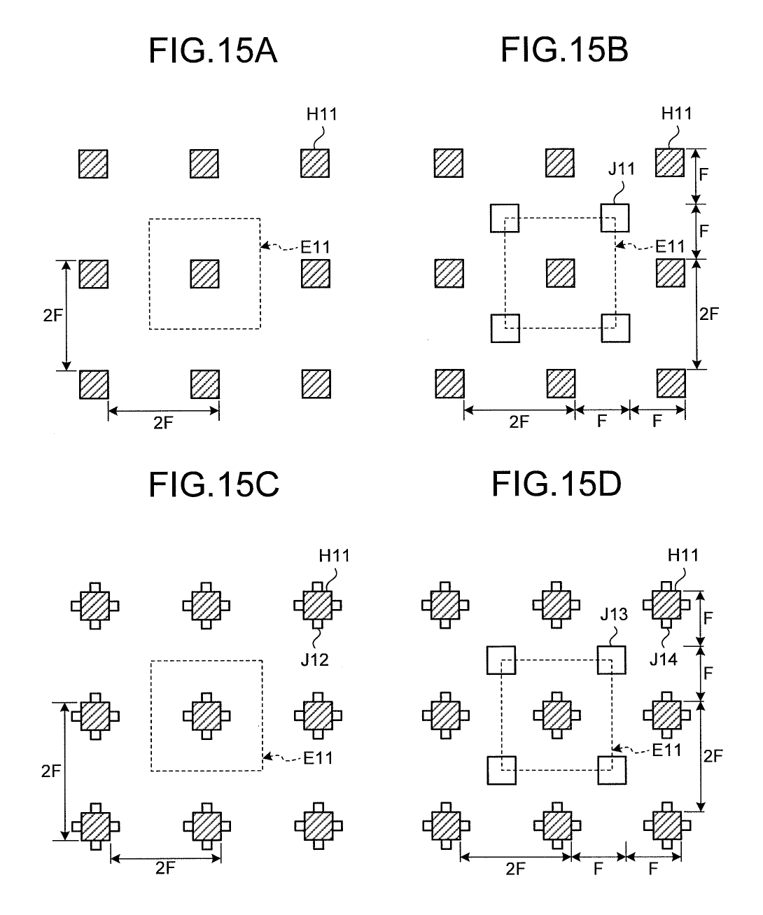

FIG. 15A is a plan view of exemplary mask patterns according to an eleventh embodiment. FIG. 15B is a plan view of exemplary mask patterns according to a twelfth embodiment. FIG. 15C is a plan view of exemplary mask patterns according to a thirteenth embodiment. FIG. 15D is a plan view of exemplary mask patterns according to a fourteenth embodiment.

In FIG. 15A, the mask patterns H11 are disposed at regular intervals. A Pitch between the mask patterns H11 can be set at 2F. In this case, the boundary of the periphery E11 of each mask pattern H11 can be set at 1F.

In FIG. 15B, to reduce light intensities at the peripheries E11 of the mask patterns H11, assist patterns J11 may be disposed at the centers between the mask patterns H11. Note that there is a need to set the size of the assist patterns J11 at a value not larger than the value of a resolution limit at the time of exposure using the mask patterns H11.

In FIG. 15C, to reduce light intensities at the peripheries E11 of the mask patterns H11, assist patterns J12 may be disposed on each side of the mask patterns H11. Note that there is a need to set the size of the assist patterns J12 at a value not larger than the value of a resolution limit at the time of exposure using the mask patterns H11.

In FIG. 15D, to reduce light intensities at the peripheries E11 of the mask patterns H11, assist patterns J13 may be disposed at the centers between the mask patterns H11, and assist patterns J14 may be disposed on each side of the mask patterns H11. Note that there is a need to set the sizes of the assist patterns J13 and J14 at values not larger than the value of a resolution limit at the time of exposure using the mask patterns H11.

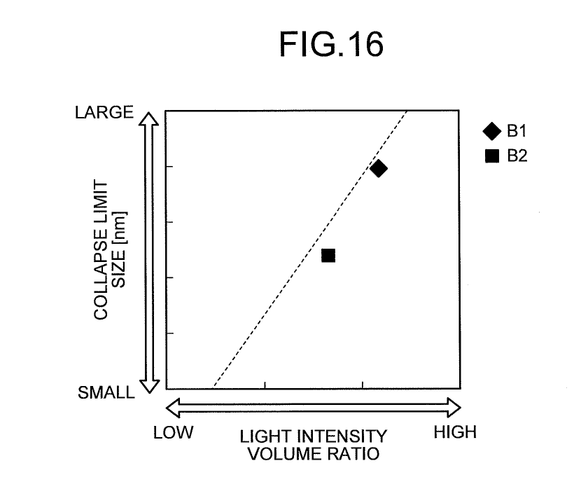

FIG. 16 is a graph showing the relationship between the light intensity volume ratios and the collapse limit sizes based on a comparison between the case of having used the mask patterns of FIG. 15A and the case of having used the mask patterns of FIG. 15B. Reference alphanumerics B1 denote the case of having used the mask patterns of FIG. 15A, and reference alphanumerics B2 denote the case of having used the mask patterns of FIG. 15B.

FIG. 16 shows that in the case where the assist patterns J11, J12, J13, or J14 are added to the mask patterns H11, the light intensity volume ratio is low compared with the case where the addition is not made, and thus the collapse limit size of the pillar patterns is reduced. Therefore the finer pillar patterns can be implemented while reducing the collapse of the pillar patterns.

### Fifteenth Embodiment

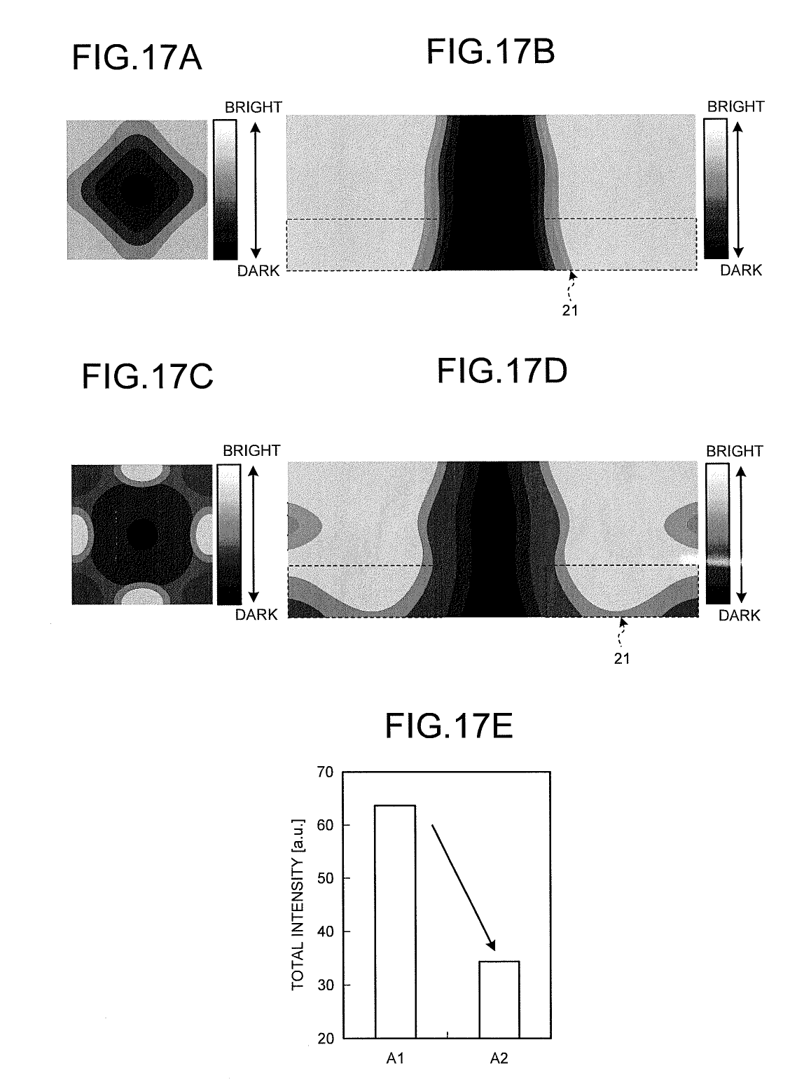

FIG. 17A is a plan view of one example of an optical image to be judged at a pattern generating apparatus according to a fifteenth embodiment. FIG. 17B is an illustration showing one example of a method of calculating a judgment index to pillar collapse based on an image intensity distribution in the optical image in FIG. 17A. FIG. 17C is a plan view of another example of the optical image to be judged at the pattern generating apparatus according to the fifteenth embodiment. FIG. 17D is an illustration showing one example of a method of calculating a judgment index to pillar collapse based on an image intensity distribution in the optical image in FIG. 17C. FIG. 17E is a graph showing a comparison between total latent image intensity at the foot of a pillar pattern of FIG. 17B and total latent image intensity at the foot of a pillar pattern of FIG. 17D. FIGS. 17A and 17B show the optical images obtained using the photo mask M1 of FIG. 4A, and FIGS. 17C and 17D show the optical images obtained using the photo mask M2 of FIG. 5A.

In the methods in FIGS. 4B and 4D, the light intensity volume ratio V_{b}/(V_{b}+V_{d}) is used as the judgment index; in the methods in FIGS. 17B and 17D can be used light intensities at the cross-section foots 21 of the peripheries of the pillar patterns transferred to the resist films R1 and R2. In the latter methods, as shown in FIG. 17E, total light intensity at the cross-section foot 21 measured in the case of having used the photo mask M2 of FIG. 5A (case A2) is low compared with the case of having used the photo mask M1 of FIG. 4A (case A1).

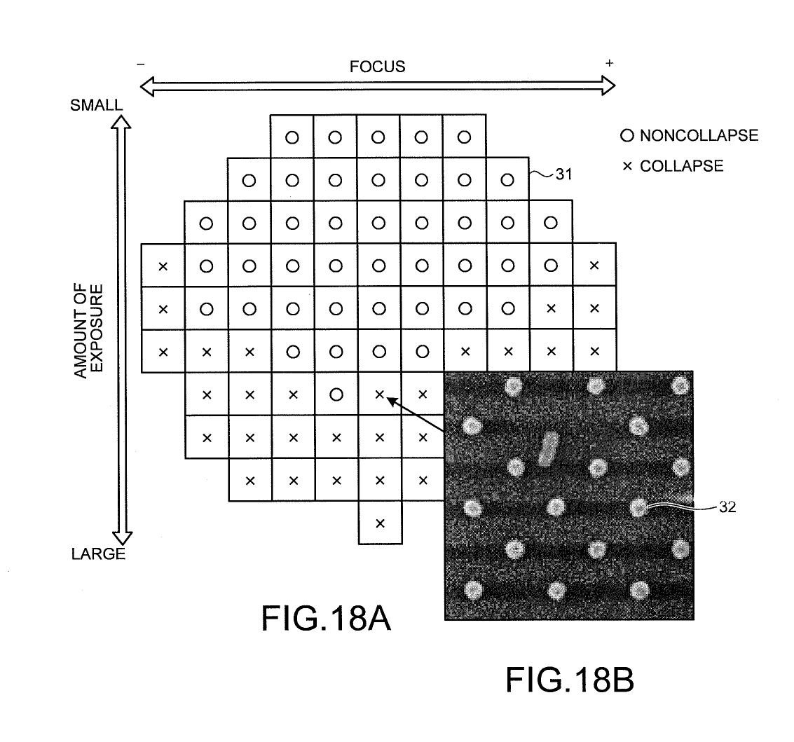

FIGS. 18A and 18B are illustrations showing the occurrence and the nonoccurrence of pillar collapse at the time when having changed the focus and the amount of the exposure in the wafer surface.

As shown in FIGS. 18A and 18B, after the change of the focus and the amount of the exposure in the surface of the wafer 31, the pillars 32 have been checked for collapse.

### Sixteenth Embodiment

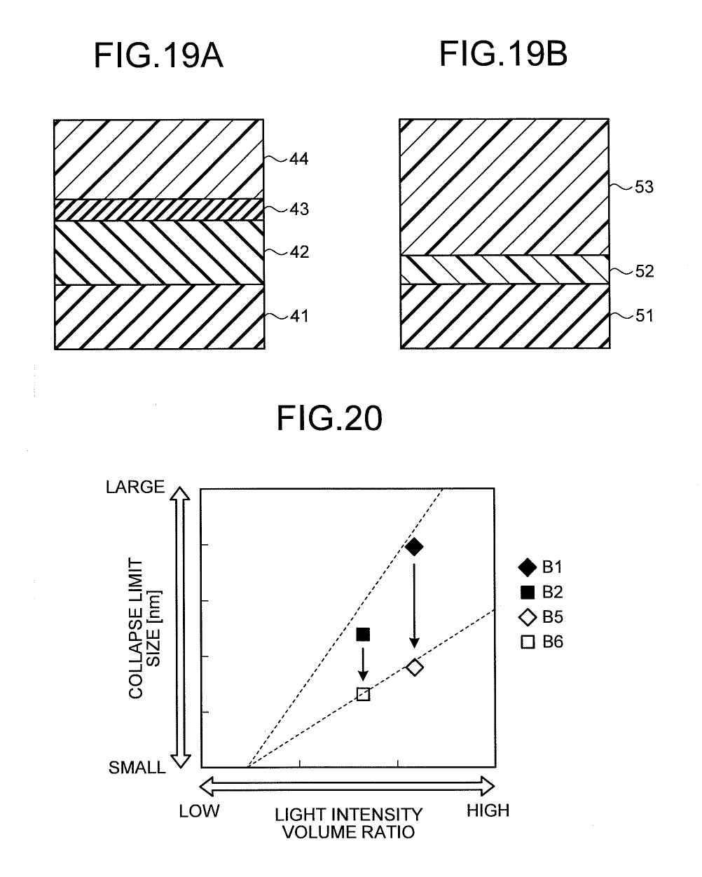

FIG. 19A is a cross-sectional view of one example of a resist film structure according to a sixteenth embodiment, and FIG. 19B is a cross-sectional view of another example of the resist film structure according to the sixteenth embodiment.

In the resist film structure of FIG. 19A, on an underlying layer 41, a carbon-coated film 42, and a SOG (spin on glass) film 43, and a resist film 44 are laminated in that order. Incidentally, in this resist film structure, the SOG film 43 is patterned using the resist film 44 as a mask, the carbon-coated film 42 is patterned using the SOG film 43 as a mask, and the underlying layer 41 is patterned using the carbon-coated film 42 as a mask. In this case, by using the carbon-coated film 42 as a mask when patterning the underlying layer 41, a selective ratio can be ensured for the underlying layer 41.

In the resist film structure of FIG. 19B, a resist film 53 is formed on an underlying layer 51 via an antireflection film 52. Note that the antireflection film 52 can be made different from the resist film 53 in refractive index.

FIG. 20 is a graph showing the relationship between the light intensity volume ratios and the collapse limit sizes based on a comparison between the case of having used the resist film structure of FIG. 19A and the case of having used the resist film structure of FIG. 19B. In FIG. 20, reference alphanumerics B1 denote the case of having used the mask pattern of FIG. 15A and the underlying layer of FIG. 19A, reference alphanumerics B2 denote the case of having used the mask pattern of FIG. 15B and the underlying layer of FIG. 19A, reference alphanumerics B5 denote the case of having used the mask pattern of FIG. 15A and the underlying layer of FIG. 19B, and reference alphanumerics B6 denote the case of having used the mask pattern of FIG. 15B and the underlying layer of FIG. 19B.

As shown in FIG. 20, the use of the underlying layer of FIG. 19B has brought about the result that the collapse limit size of the pillar patterns is reduced. This is because it can be considered that there is a difference in adhesion between the resist film and the underlying layer. That is, it is important to find a match between a resist material and an underlying film.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A pattern generating apparatus comprising:
a light intensity calculating part that calculates light intensity at a pattern to be formed based on exposure and light intensity at a periphery of the pattern;
a light intensity evaluating part that evaluates the light intensities at the pattern and the periphery of the pattern; and
a data output part that output correction data for the pattern based on results of the evaluations by the light intensity evaluating part.

2. The pattern generating apparatus according to claim 1, wherein an evaluation index to the light intensities at the pattern and the periphery of the pattern is a volume ratio between the light intensity at the pattern and the light intensity at the periphery of the pattern, a volume of the light intensity at the pattern and a volume of the light intensity at the periphery of the pattern, a ratio between the maximum value and the minimum value of the light intensities at the pattern and the periphery of the pattern, or light intensity at the cross-section foot of the periphery of the pattern.

3. The pattern generating apparatus according to claim 2, wherein the light intensity volume ratio is expressed by an expression V_{b}/(V_{b}+V_{d}) where V_{b} is a bright portion volume in an optical image used to form a pillar pattern or a hole pattern as the pattern, and V_{d} is a dark portion volume in the optical image.

4. The pattern generating apparatus according to claim 3, wherein in a case where the pillar pattern or the hole pattern is disposed at a regular interval, a boundary of the periphery of the pillar pattern or the hole pattern is set at the regular interval.

5. The pattern generating apparatus according to claim 1, wherein the correction data is correction data for layout design data corresponding to the pattern, correction data for a mask pattern corresponding to the pattern, or correction data for an exposure condition for the pattern.

6. The pattern generating apparatus according to claim 5, wherein the exposure condition is a lighting form, Numerical Apertures of an optical lighting system, an irradiation wavelength, a resist material, polarization, focus, aberration or an amount of exposure.

7. A pattern generating program that makes a computer execute:
a step of calculating light intensity at a pattern to be formed by exposure and light intensity at a periphery of the pattern;
a step of evaluating the light intensities at the pattern and the periphery of the pattern; and
a step of outputting correction data for the pattern based on results of the evaluations.

8. The pattern generating program according to claim 7, wherein an evaluation index to the light intensities at the pattern and the periphery of the pattern is a volume ratio between the light intensity at the pattern and the light intensity at the periphery of the pattern, a volume of the light intensity at the pattern and a volume of the light intensity at the periphery of the pattern, a ratio between the maximum value and the minimum value of the light intensities at the pattern and the periphery of the pattern, or light intensity at the cross-section foot of the periphery of the pattern.

9. The pattern generating program according to claim 8, wherein the light intensity volume ratio is expressed by an expression V_{b}/(V_{b}+V_{d}) where V_{b} is a bright portion volume in an optical image used to form a pillar pattern or a hole pattern as the pattern, and V_{d} is a dark portion volume in the optical image.

10. The pattern generating program according to claim 9, wherein in a case where the pillar pattern or the hole pattern is disposed at a regular interval, a boundary of the periphery of the pillar pattern or the hole pattern is set at the regular interval.

11. The pattern generating program according to claim 8, wherein the correction data is correction data for layout design data corresponding to the pattern, correction data for a mask pattern corresponding to the pattern, or correction data for an exposure condition for the pattern.

12. The pattern generating program according to claim 11, wherein the exposure condition is a lighting form, Numerical Apertures of an optical lighting system, an irradiation wavelength, a resist material, polarization, focus, aberration or an amount of exposure.

13. A method for fabricating a semiconductor device, the method comprising:
adding an assist pattern having a size not larger than a value of a resolution limit at the time of exposure to a mask pattern corresponding to a pattern to be formed by the exposure, based on light intensity at the pattern and light intensity at the periphery of the pattern;
exposing resist films on underlying layers via the mask pattern;
developing the exposed resist films to transfer the pattern to the resist films; and
processing the underlying layers by using the pattern-transferred resist films as masks.

14. The method for fabricating a semiconductor device according to claim 13, the assist pattern is disposed next to the mask pattern.

15. The method for fabricating a semiconductor device according to claim 13, wherein the assist pattern is disposed between mask patterns.

16. A method for fabricating a semiconductor device, the method comprising:
checking a finished shape of a resist pattern to be formed by exposure based on light intensity at the resist pattern and light intensity at the periphery of the resist pattern; and
determining layout design data for the resist pattern, a mask pattern, or an exposure condition based on a result of the check on the finished size of the resist pattern.

17. The method for fabricating a semiconductor device according to claim 16, wherein an evaluation index to the light intensities at the pattern and the periphery of the pattern is a volume ratio between the light intensity at the pattern and the light intensity at the periphery of the pattern, a volume of the light intensity at the pattern and a volume of the light intensity at the periphery of the pattern, a ratio between a maximum value and a minimum value of the light intensities at the pattern and the periphery of the pattern, or light intensity at the cross-section foot of the periphery of the pattern.

18. The method for fabricating a semiconductor device according to claim 17, wherein the light intensity volume ratio is expressed by an expression V_{b}/(V_{b}+V_{d}) where V_{b} is a bright portion volume in an optical image used to form a pillar pattern or a hole pattern as the pattern, and V_{d} is a dark portion volume in the optical image.

19. The method for fabricating a semiconductor device according to claim 18, wherein in a case where the pillar pattern or the hole pattern is disposed at a regular interval, a boundary of the periphery of the pillar pattern or the hole pattern is set at the regular interval.

20. The method for fabricating a semiconductor device according to claim 16, wherein the exposure condition is a lighting form, Numerical Apertures of an optical lighting system, an irradiation waveform, or an amount of exposure.
